(19) United States
(12) Patent Application Publication
(10) Pub. No.: US 2026/0068199 A1
(43) Pub. Date: Mar. 5, 2026

(54) SILICON-GERMANIUM HETEROJUNCTION BIPOLAR TRANSISTOR AND METHOD FOR MANUFACTURING THE SAME

(71) Applicants: Semiconductor Technology Innovation Center (Beijing) Corporation (STIC), Beijing (CN); Tsinghua University, Beijing City (CN)

(72) Inventors: Jun Fu, Beijing (CN); Yue Zhao, Beijing (CN); Kai Zheng, Beijing (CN); Yikang Zhou, Beijing (CN)

(21) Appl. No.: 19/198,449

(22) Filed: May 5, 2025

(30) Foreign Application Priority Data
Aug. 27, 2024 (CN) 202411187905.4

(51) Int. Cl. H10D 10/01; H10D 62/13; H10D 62/17; H10D 84/03

(52) U.S. Cl. CPC H10D 10/021; H10D 62/137; H10D 62/177; H10D 84/038

(57) ABSTRACT

Disclosed in the present disclosure are a silicon-germanium heterojunction bipolar transistor and a method for manufacturing the same, which relate to a field of semiconductor technologies. The silicon-germanium heterojunction bipolar transistor and the method for manufacturing the same of the present disclosure can achieve the purpose of exposing a part of the sidewall of the polysilicon extrinsic base region, so as to make a necessary space for subsequently growing the silicon-germanium connection base region synchronously with the silicon-germanium epitaxial intrinsic base region, and implement a recessed silicon-germanium connection base region structure which can effectively improve the device performance. In addition, the silicon-germanium heterojunction bipolar transistor of the present disclosure may be manufactured by adopting process steps with low process difficulty and complexity, and then effectively improving the repeatability, uniformity, controllability and manufacturability of the related integrated circuit process production.

### CROSS REFERENCE TO RELATED APPLICATIONS

This application claims priority to Chinese Application Number 202411187905.4, filed on Aug. 27, 2024, which is hereby incorporated by reference in its entirety.

### TECHNICAL FIELD

The present disclosure relates to the field of semiconductor device and integrated circuit process design and manufacturing, and particularly to a silicon-germanium heterojunction bipolar transistor and a method for manufacturing the same.

### BACKGROUND

The structure of a self-aligned silicon-germanium heterojunction bipolar transistor 001 with a selective silicon-germanium epitaxial intrinsic base region based on isotropic etching of a silicon nitride inner sidewall is illustrated in FIG. 1. The key process step of the heterojunction bipolar transistor 001 is that, as illustrated in FIGS. 2a and 2b (which are schematic diagrams of device structures before and after the key process step, respectively), by the isotropic etching of a silicon nitride inner sidewall 1 and the use of a slit gap 4 reserved at a bottom of the silicon nitride inner sidewall 1 by a precise thickness control during the selective growth of a silicon epitaxial layer 2 in a collector region, the “undercut” etching of a part of the silicon nitride inner sidewall 1 is realized to expose a part of the sidewall of an extrinsic base region polysilicon layer 3 are realized. This process is complicated. The process complexity and difficulty are quite high, and the process controllability, repeatability and uniformity are relatively poor.

This section is intended to provide a background or context for the embodiments of the present disclosure that are set forth in the claims. The description herein is not admitted to be the prior art by virtue of its inclusion in this section.

### SUMMARY

In order to solve at least one of the above problems existing in the prior art, the embodiments of the present disclosure provide a silicon-germanium heterojunction bipolar transistor and a method for manufacturing the same.

According to a first aspect of the embodiments of the present disclosure, the present disclosure provides a silicon-germanium heterojunction bipolar transistor, comprising:
a substrate;
a heavily doped silicon collector region with a conductivity type opposite to that of the substrate, and formed on an upper side of the substrate;
a field region dielectric layer formed on the upper side of the substrate;
a first silicon oxide layer formed on upper sides of the heavily doped silicon collector region and the field region dielectric layer;
a silicon epitaxial collector region with a conductivity type the same as that of the heavily doped silicon collector region, and formed on the upper side of the heavily doped silicon collector region;
a heavily doped polysilicon extrinsic base region with a conductivity type opposite to that of the heavily doped silicon collector region, and formed on the first silicon oxide layer;
a silicon-germanium base region with a conductivity type the same as that of the polysilicon extrinsic base region, comprising: a silicon-germanium epitaxial intrinsic base region formed on an upper side of the silicon epitaxial collector region, and a silicon-germanium connection base region formed on the upper side of the first silicon oxide layer and between the silicon-germanium epitaxial intrinsic base region and the polysilicon extrinsic base region;
a second silicon oxide layer formed between the polysilicon extrinsic base region and a silicon nitride layer;
the silicon nitride layer formed between the second silicon oxide layer and a polysilicon emitter region;
a silicon nitride inner sidewall formed on an upper side of the silicon-germanium connection base region
an L-shaped silicon oxide inner sidewall formed on an upper side of the silicon-germanium epitaxial intrinsic base region and inner and upper sides of the silicon nitride inner sidewall;
a heavily doped polysilicon emitter region with a conductivity type the same as that of the heavily doped silicon collector region, and formed on upper sides of the silicon nitride layer, the L-shaped silicon oxide inner sidewall and the silicon-germanium epitaxial intrinsic base region; and
a heavily doped single crystal emitter region with a conductivity type the same as that of the polysilicon emitter region, and formed in the silicon-germanium epitaxial intrinsic base region between the L-shaped silicon oxide inner sidewalls; wherein,
a recessed structure is formed in the first silicon oxide layer close to the silicon epitaxial collector region and the polysilicon extrinsic base region, and the silicon-germanium connection base region is formed on an upper side of the recessed structure of the first silicon oxide layer.

In some embodiments, the silicon-germanium heterojunction bipolar transistor further comprises:
a dielectric outer sidewall formed outside the first silicon oxide layer, the polysilicon extrinsic base region, the second silicon oxide layer, the silicon nitride layer and the polysilicon emitter region.

In some embodiments, the silicon-germanium heterojunction bipolar transistor further comprises:
a self-aligned silicide layer formed on the upper sides of the polysilicon emitter region and the polysilicon extrinsic base region, and self-aligned separated by the dielectric outer sidewall.

According to a second aspect of the embodiments of the present disclosure, the present disclosure provides a method for manufacturing a silicon-germanium heterojunction bipolar transistor, comprising:
providing a silicon-based bipolar transistor infrastructure, wherein the silicon-based bipolar transistor infrastructure comprises a substrate, and a heavily doped silicon collector region with a conductivity type opposite to that of the substrate and a field region dielectric layer which are formed on the substrate;
sequentially depositing and forming a first silicon oxide layer, a heavily doped polysilicon extrinsic base region with a conductivity type opposite to that of the heavily doped silicon collector region, a second silicon oxide layer and a silicon nitride layer on the silicon-based bipolar transistor infrastructure;
forming a collector region window along a thickness direction of the silicon nitride layer, the second silicon oxide layer and the polysilicon extrinsic base region to partially expose the first silicon oxide layer;
etching the first silicon oxide layer below the collector region window to partially expose the heavily doped silicon collector region;
taking the exposed heavily doped silicon collector region as seed crystal to selectively grow a silicon epitaxial collector region, so that an upper surface of the silicon epitaxial collector region is flush with an upper surface of the first silicon oxide layer;
forming a third silicon oxide layer on the upper surface of the silicon epitaxial collector region, so that a thickness of the third silicon oxide layer is equal to that of a subsequent silicon-germanium epitaxial intrinsic base region;
forming a silicon nitride inner sidewall on an edge of the collector region window on an upper side of the third silicon oxide layer;
wet-etching the third silicon oxide layer, and etching a part of the first silicon oxide layer under the third silicon oxide layer, so as to form a recessed structure at the junction of the first silicon oxide layer with the silicon epitaxial collector region and the polysilicon extrinsic base region;
taking the exposed silicon epitaxial collector region and polysilicon extrinsic base region as seed crystal to grow a silicon-germanium base region with a conductivity type the same as that of the polysilicon extrinsic base region, to obtain a silicon-germanium epitaxial intrinsic base region on an upper side of the silicon epitaxial collector region and a silicon-germanium connection base region that connects the polysilicon extrinsic base region and the silicon-germanium epitaxial intrinsic base region;
forming an L-shaped silicon oxide inner sidewall inside the silicon nitride inner sidewall;
depositing and forming a polysilicon emitter region with a conductivity type the same as that of the heavily doped silicon collector region; and
performing rapid thermal annealing, so that impurities in the polysilicon emitter region are diffused into the silicon-germanium epitaxial intrinsic base region to form a single crystal emitter region.

In some embodiments, etching the first silicon oxide layer below the collector region window to partially expose the heavily doped silicon collector region comprises:
depositing and then anisotropically dry-etching a sacrificial silicon nitride layer to form a sacrificial silicon nitride inner sidewall at an edge of the collector region window;
anisotropically dry-etching the first silicon oxide layer by taking the silicon nitride layer and the sacrificial silicon nitride inner sidewall as masks, so that a portion of the bottom of the first silicon oxide layer under the window of the collector region remains; and
isotropically wet-etching the first silicon oxide layer by taking the silicon nitride layer and the sacrificial silicon nitride inner sidewall as masks, so that the silicon oxide layer remaining at the bottom is completely etched to partially expose the heavily doped silicon collector region, and at the same time, an inner side of the first silicon oxide layer is etched by a corresponding thickness.

In some embodiments, after taking the exposed heavily doped silicon collector region as seed crystal to selectively grow a silicon epitaxial collector region, so that an upper surface of the silicon epitaxial collector region is flush with an upper surface of the first silicon oxide layer, and before forming a third silicon oxide layer on the upper surface of the silicon epitaxial collector region, the method further comprises:
taking the silicon nitride layer, the second silicon oxide layer, the polysilicon extrinsic base region and the sacrificial silicon nitride inner sidewall as masks, performing ion implantation of selectively implanted collector on the silicon epitaxial collector region, wherein the conductivity type of implanted impurities is the same as that of the heavily doped silicon collector region.

In some embodiments, forming a third silicon oxide layer on the upper surface of the silicon epitaxial collector region, so that a thickness of the third silicon oxide layer is equal to that of a subsequent silicon-germanium epitaxial intrinsic base region comprises:
wet-etching the sacrificial silicon nitride inner sidewall;
depositing a third silicon oxide layer with a thickness exceeding a total thickness of the polysilicon extrinsic base region, the second silicon oxide layer and the silicon nitride layer;
planarized-etching back the third silicon oxide layer by taking the silicon nitride layer as a stop layer; and
continuing to anisotropically dry-etch the third silicon oxide layer by taking the silicon nitride layer as a mask, so that a remaining thickness of the third silicon oxide layer is equal to that of a subsequent silicon-germanium epitaxial intrinsic base region.

In some embodiments, forming an L-shaped silicon oxide inner sidewall inside the silicon nitride inner sidewall comprises:
depositing a fourth silicon oxide layer;
depositing a polysilicon layer on the fourth silicon oxide layer;
anisotropically dry-etching the polysilicon layer to form a polysilicon inner sidewall; and
wet-etching the exposed fourth silicon oxide layer by taking the polysilicon inner sidewall as a mask to form an L-shaped silicon oxide inner sidewall.

In some embodiments, depositing and forming a polysilicon emitter region with a conductivity type the same as that of the heavily doped silicon collector region comprises:
depositing an emitter region polysilicon layer with a conductivity type the same as that of the heavily doped silicon collector region;
etching the emitter region polysilicon layer, the silicon nitride layer and the second silicon oxide layer by taking an emitter photoresist as a mask to form a polysilicon emitter region; and
removing the emitter photoresist.

In some embodiments, after removing the emitter photoresist, and before performing rapid thermal annealing, the method further comprises:
etching the polysilicon extrinsic base region and the first silicon oxide layer by taking a base photoresist as a mask;
removing the base photoresist; and
depositing an outer sidewall dielectric layer;
after performing rapid thermal annealing, so that impurities in the polysilicon emitter region are diffused into the silicon-germanium epitaxial intrinsic base region to form a single crystal emitter region, the method further comprises:
anisotropically dry-etching the outer sidewall dielectric layer to form a dielectric outer sidewall.

In some embodiments, after forming the dielectric outer sidewall, the method further comprises:
forming a self-aligned silicide layer on the upper sides of the exposed polysilicon emitter region and polysilicon extrinsic base region, wherein the self-aligned silicide layer is self-aligned separated by the dielectric outer sidewall.

The silicon-germanium heterojunction bipolar transistor and the method for manufacturing the same of the present disclosure can achieve the purpose of exposing a part of the sidewall of the polysilicon extrinsic base region, so as to make a necessary space for subsequently growing the silicon-germanium connection base region synchronously with the silicon-germanium epitaxial intrinsic base region, and implement a recessed silicon-germanium connection base region structure which can effectively improve the device performance. In addition, the silicon-germanium heterojunction bipolar transistor of the present disclosure may be manufactured by adopting process steps with low process difficulty and complexity, thus avoiding the uncontrollable process step in the background art of isotropically etching the silicon nitride sidewall by “undercutting” with a bottom slit, and then effectively improving the repeatability, uniformity, controllability and manufacturability of the related integrated circuit process production.

### BRIEF DESCRIPTION OF THE DRAWINGS

In order to more clearly explain the technical solutions in the embodiments of the present disclosure or in the prior art, the drawings required for describing the embodiments or the prior art will be briefly introduced below. Obviously, the drawings involved in the following description just illustrate some embodiments of the present disclosure, and those of ordinary skills in the art can obtain other drawings from them without paying any creative effort. In the drawings:

FIG. 1 illustrates a schematic structural diagram of a self-aligned silicon-germanium heterojunction bipolar transistor with a selective silicon-germanium epitaxial intrinsic base region based on isotropic etching of a silicon nitride inner sidewall.

FIGS. 2a and 2b illustrate schematic structural diagrams of a self-aligned silicon-germanium heterojunction bipolar transistor with a selective silicon-germanium epitaxial intrinsic base region based on isotropic etching of a silicon nitride inner sidewall before and after key process steps, respectively.

FIGS. 3 to 27 sequentially illustrate schematic diagrams of semiconductor structures obtained by respective process steps of a method for manufacturing a silicon-germanium heterojunction bipolar transistor according to an embodiment of the present disclosure.

FIG. 28 illustrates a flowchart of a method for manufacturing a silicon-germanium heterojunction bipolar transistor according to an embodiment of the present disclosure.

FIG. 29 illustrates a partial flowchart of a method for manufacturing a silicon-germanium heterojunction bipolar transistor according to an embodiment of the present disclosure.

FIG. 30 illustrates a partial flowchart of a method for manufacturing a silicon-germanium heterojunction bipolar transistor according to an embodiment of the present disclosure.

FIG. 31 illustrates a partial flowchart of a method for manufacturing a silicon-germanium heterojunction bipolar transistor according to an embodiment of the present disclosure.

FIG. 32 illustrates a partial flowchart of a method for manufacturing a silicon-germanium heterojunction bipolar transistor according to an embodiment of the present disclosure.

FIG. 33 illustrates a partial flowchart of a method for manufacturing a silicon-germanium heterojunction bipolar transistor according to an embodiment of the present disclosure.

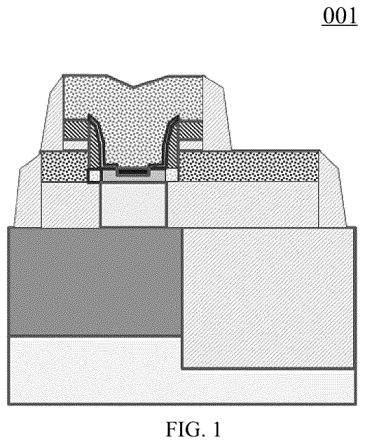

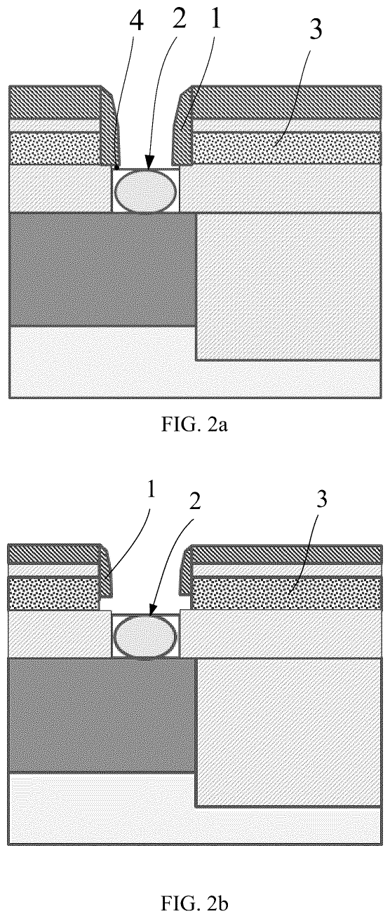

### DESCRIPTION OF EMBODIMENTS

The technical solutions in the embodiments of the present disclosure will be clearly and completely described below with reference to the drawings for the embodiments of the present disclosure. Obviously, those described are only a part, rather than all, of the embodiments of the present disclosure. Based on the embodiments in the present disclosure, any other embodiment obtained by those of ordinary skill in the art without paying any creative effort should fall within the protection scope of the present disclosure.

The specific embodiments of the present disclosure are disclosed in detail with reference to the following description and drawings, and the ways in which the principles of the present disclosure can be adopted are pointed out. It should be understood that the embodiments of the present disclosure are not limited in scope thereby. The embodiments of the present disclosure include many changes, modifications and equivalents within the spirit and scope of the appended claims.

Features described and/or illustrated for one embodiment may be used in one or more other embodiments in the same or similar way, and in combination with, or in substitution for, features in other embodiments.

It should be emphasized that the term “comprise/include” as used herein refers to the presence of a feature, integer, step or component, but does not exclude the presence or addition of one or more other features, integers, steps or components.

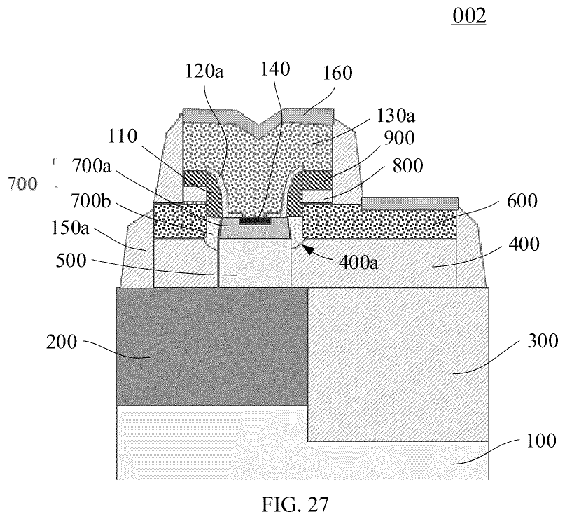

In order to solve at least one of the above problems existing in the prior art, in a first aspect, the present disclosure provides a silicon-germanium heterojunction bipolar transistor 002 as illustrated in FIG. 27, which includes:
a substrate 100;
a heavily doped silicon collector region 200 with a conductivity type opposite to that of the substrate 100, and formed on an upper side of the substrate 100;
a field region dielectric layer 300 formed on the upper side of the substrate 100;
a first silicon oxide layer 400 formed on upper sides of the heavily doped silicon collector region 200 and the field region dielectric layer 300;
a silicon epitaxial collector region 500 with a conductivity type the same as that of the heavily doped silicon collector region 200, and formed on the upper side of the heavily doped silicon collector region 200;
a heavily doped polysilicon extrinsic base region 600 with a conductivity type opposite to that of the heavily doped silicon collector region 200, and formed on the first silicon oxide layer 400;
a silicon-germanium base region 700 with a conductivity type the same as that of the polysilicon extrinsic base region 600, including: a silicon-germanium epitaxial intrinsic base region 700a formed on an upper side of the silicon epitaxial collector region 500, and a silicon-germanium connection base region 700b formed on the upper side of the first silicon oxide layer 400 and between the silicon-germanium epitaxial intrinsic base region 700a and the polysilicon extrinsic base region 600;
a second silicon oxide layer 800 formed between the polysilicon extrinsic base region 600 and a silicon nitride layer 900;
the silicon nitride layer 900 formed between the second silicon oxide layer 800 and a polysilicon emitter region 130a;
a silicon nitride inner sidewall 110 formed on an upper side of the silicon-germanium connection base region 700b;
an L-shaped silicon oxide inner sidewall 120a formed on an upper side of the silicon-germanium epitaxial intrinsic base region 700a and inner and upper sides of the silicon nitride inner sidewall 110;
a heavily doped polysilicon emitter region 130a with a conductivity type the same as that of the heavily doped silicon collector region 200, and formed on upper sides of the silicon nitride layer 900, the L-shaped silicon oxide inner sidewall 120a and the silicon-germanium epitaxial intrinsic base region 700a; and
a heavily doped single crystal emitter region 140 with a conductivity type the same as that of the polysilicon emitter region 130a, and formed in the silicon-germanium epitaxial intrinsic base region 700a between the L-shaped silicon oxide inner sidewalls 120a; wherein,
a recessed structure 400a is formed in the first silicon oxide layer 400 close to the silicon epitaxial collector region 500 and the polysilicon extrinsic base region 600, and the silicon-germanium connection base region 700b is formed on an upper side of the recessed structure 400a of the first silicon oxide layer 400.

The silicon-germanium heterojunction bipolar transistor of the present disclosure can achieve the purpose of exposing a part of the sidewall of the polysilicon extrinsic base region 600, so as to make a necessary space for subsequently growing the silicon-germanium connection base region 700b synchronously with the silicon-germanium epitaxial intrinsic base region 700a. However, the silicon-germanium heterojunction bipolar transistor of the present disclosure may be manufactured by adopting process steps with low process difficulty and complexity, thus avoiding the uncontrollable process step in the background art of isotropically etching the silicon nitride sidewall by “undercutting” with a bottom slit, and then effectively improving the repeatability, uniformity, controllability and manufacturability of the related integrated circuit process production.

In addition, compared with the background art, the device structure proposed in the present disclosure also has different characteristics, which are mainly embodied in that the silicon-germanium connection base region 700b presents a recessed structure, i.e., the silicon-germanium connection base region 700b is the thinnest at one end connected to the polysilicon extrinsic base 600, and gradually thickened from the end to the silicon-germanium epitaxial intrinsic base 700a until the other end connected to the silicon-germanium epitaxial intrinsic base 700a reaches the thickest, so that the overall thickness is relatively large, and thus a smaller parasitic base series resistance can be obtained compared with the background art, which is beneficial to improving the radio frequency noise performance of the device. Of course, the thickness of the silicon-germanium connection base region 700b of the silicon-germanium heterojunction bipolar transistor in the present disclosure is increased by etching the first silicon oxide layer 400 therebelow, so it is inevitable to pay the price that the thickness of the first silicon oxide layer 400 is partially reduced, resulting in the increase of the base-collector parasitic capacitance. However, the thinned part of the first silicon oxide layer 400 accounts for a small proportion of the overall first silicon oxide layer 400, and a compromise relationship between the parasitic base series resistance and the base-collector parasitic capacitance can be optimized by comprehensively exploring an optimal depression degree of the silicon-germanium connection base region 700b, thereby improving the radio frequency power gain performance of the device to the greatest extent, so that a performance index of a highest oscillation frequency of the device can be actually improved compared with the background art. Furthermore, the recessed structure of the silicon-germanium connection base region 700b also causes the silicon-germanium connection base region 700b and the silicon epitaxial collector region 500 to form a lateral pn junction, which has a modulation effect on the related potential and electric field of the longitudinal pn junction between the silicon-germanium epitaxial intrinsic base region 700a and the silicon epitaxial collector region 500. The reasonable use of this modulation can reduce an electric field intensity originally determined only by the longitudinal pn junction between the silicon-germanium epitaxial intrinsic base region 700a and the silicon epitaxial collector region 500, thus effectively improving a breakdown voltage index of the device, and further improving the comprehensive optimization of performance indexes such as a speed and a frequency response and a withstand voltage index of the device.

As illustrated in FIG. 27, in some embodiments, the silicon-germanium heterojunction bipolar transistor 002 further includes:
a dielectric outer sidewall 150a formed outside the first silicon oxide layer 400, the polysilicon extrinsic base region 600, the second silicon oxide layer 800, the silicon nitride layer 900 and the polysilicon emitter region 130a.

As illustrated in FIG. 27, in some embodiments, the silicon-germanium heterojunction bipolar transistor 002 further includes:
a self-aligned silicide layer 160 formed on the upper sides of the polysilicon emitter region 130a and the polysilicon extrinsic base region 600, and self-aligned separated by the dielectric outer sidewall 150a.

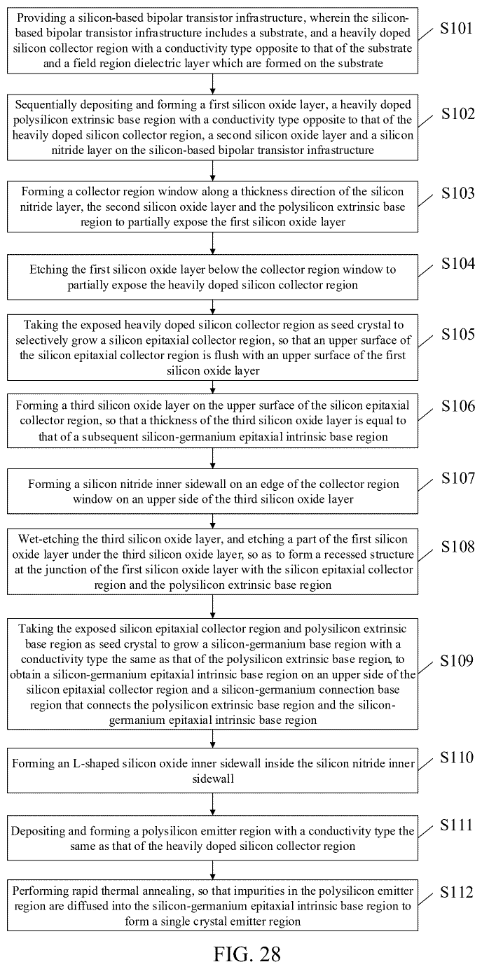

In order to solve at least one of the above problems existing in the prior art, in a second aspect, the present disclosure provides a method for manufacturing a silicon-germanium heterojunction bipolar transistor as illustrated in FIG. 28, which includes:

S101: providing a silicon-based bipolar transistor infrastructure, wherein the silicon-based bipolar transistor infrastructure includes a substrate, and a heavily doped silicon collector region with a conductivity type opposite to that of the substrate and a field region dielectric layer which are formed on the substrate.

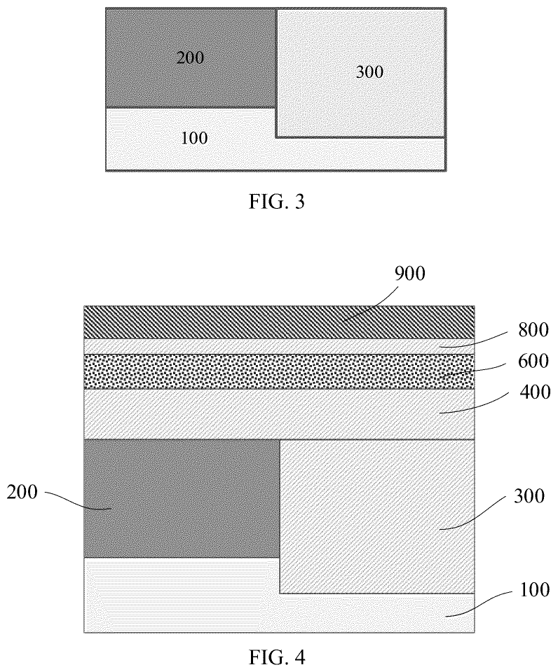

In step S101, as illustrated in FIG. 3, the silicon-germanium heterojunction bipolar transistor proposed in the present disclosure starts from a silicon-based bipolar transistor infrastructure including a substrate 100, a heavily doped silicon collector region 200 and a field region dielectric layer 300, wherein the substrate 100 may be a lightly doped silicon substrate of a first conductivity type, the heavily doped silicon collector region 200 may be a heavily doped buried silicon collector region or a silicon collector region well of a second conductivity type (opposite to the conductivity type of the substrate 100), and the field region dielectric layer 300 may be a field region silicon oxide layer.

S102: sequentially depositing and forming a first silicon oxide layer, a heavily doped polysilicon extrinsic base region with a conductivity type opposite to that of the heavily doped silicon collector region, a second silicon oxide layer and a silicon nitride layer on the silicon-based bipolar transistor infrastructure.

In step S102, as illustrated in FIG. 4, a first silicon oxide layer 400, a heavily doped polysilicon extrinsic base region 600 with a conductivity type opposite to that of the heavily doped silicon collector region 200, a second silicon oxide layer 800 and a silicon nitride layer 900 are sequentially deposited and formed on the silicon-based bipolar transistor infrastructure; wherein the polysilicon extrinsic base region 600 specifically may be a polysilicon layer heavily doped with impurities of the first conductivity type in situ.

S103: forming a collector region window along a thickness direction of the silicon nitride layer, the second silicon oxide layer and the polysilicon extrinsic base region to partially expose the first silicon oxide layer.

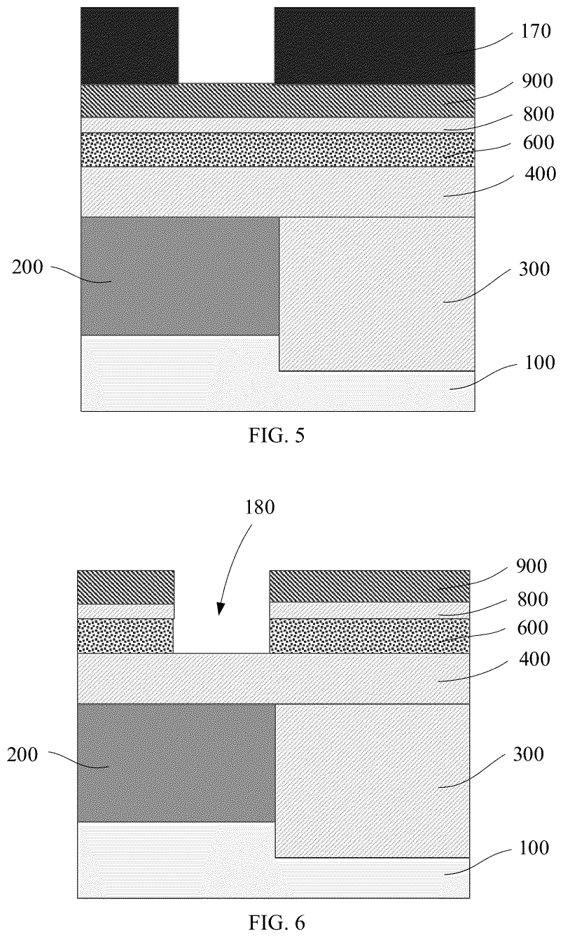

In step S103, as illustrated in FIGS. 5 and 6, the silicon nitride layer 900, the second silicon oxide layer 800 and the polysilicon extrinsic base region 600 are sequentially etched with a photoresist 170 as a mask to expose the first silicon oxide layer 400 therebelow, and then the photoresist 170 is removed to form a collector region window 180.

S104: etching the first silicon oxide layer below the collector region window to partially expose the heavily doped silicon collector region.

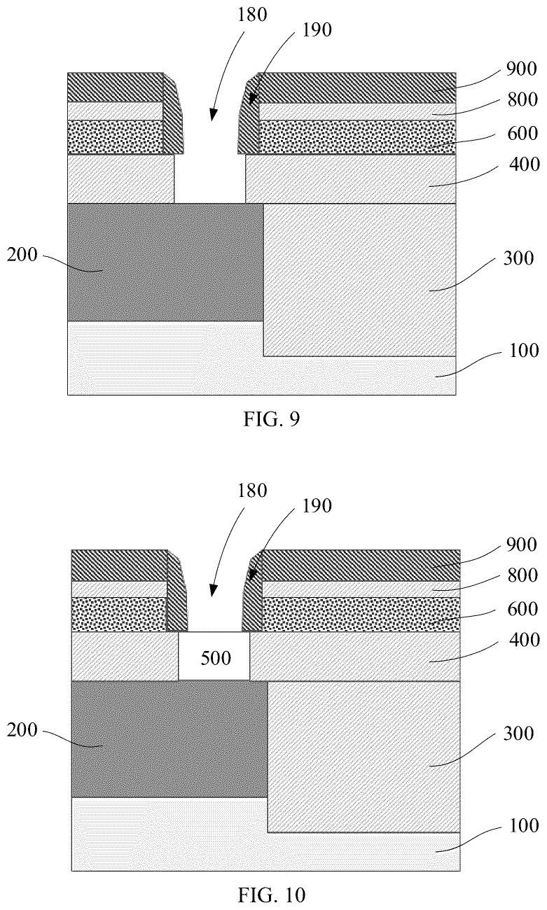

In step S104, as illustrated in FIG. 9, the first silicon oxide layer 400 below the collector region window 180 is etched to partially expose the heavily doped silicon collector region 200.

S105: taking the exposed heavily doped silicon collector region as seed crystal to selectively grow a silicon epitaxial collector region, so that an upper surface of the silicon epitaxial collector region is flush with an upper surface of the first silicon oxide layer.

In step S105, as illustrated in FIG. 10, the exposed heavily doped silicon collector region 200 is taken as seed crystal to selectively grow a silicon epitaxial collector region 500, so that an upper surface of the silicon epitaxial collector region 500 is flush with an upper surface of the first silicon oxide layer 400.

S106: forming a third silicon oxide layer on the upper surface of the silicon epitaxial collector region, so that a thickness of the third silicon oxide layer is equal to that of a subsequent silicon-germanium epitaxial intrinsic base region.

In step S106, as illustrated in FIG. 15, a third silicon oxide layer 210 is formed on the upper surface of the silicon epitaxial collector region 500, so that a thickness of the third silicon oxide layer 210 is equal to that of a subsequent silicon-germanium epitaxial intrinsic base region 700a.

S107: forming a silicon nitride inner sidewall on an edge of the collector region window on an upper side of the third silicon oxide layer.

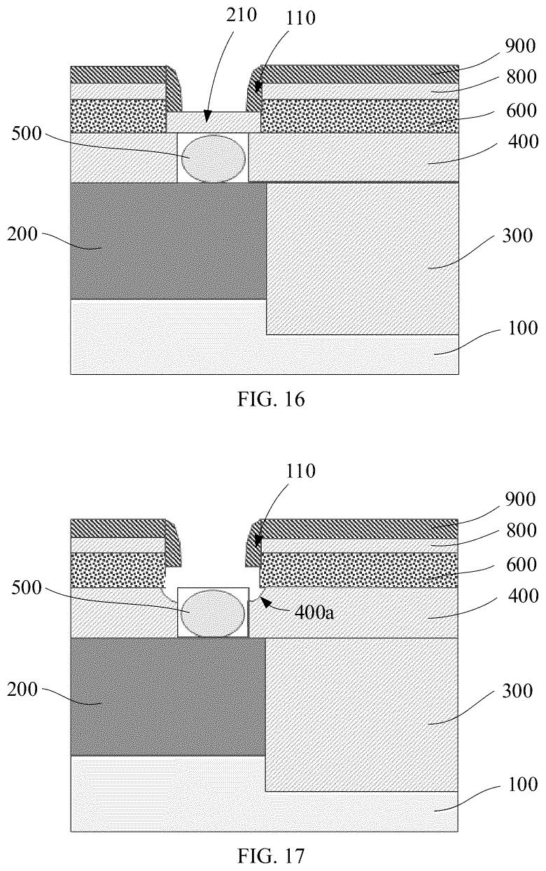

In step S107, as illustrated in FIG. 16, a silicon nitride inner sidewall 110 is formed by depositing silicon nitride and then anisotropic dry-etching the silicon nitride.

S108: wet-etching the third silicon oxide layer, and etching a part of the first silicon oxide layer under the third silicon oxide layer, so as to form a recessed structure at the junction of the first silicon oxide layer with the silicon epitaxial collector region and the polysilicon extrinsic base region.

In step S108, as illustrated in FIG. 17, the third silicon oxide layer 210 in the collector region window 18 is wet-etched, and a part of the first silicon oxide layer 400 therebelow is etched by over-etching, thereby forming a recessed structure 400a.

S109: taking the exposed silicon epitaxial collector region and polysilicon extrinsic base region as seed crystal to grow a silicon-germanium base region with a conductivity type the same as that of the polysilicon extrinsic base region, to obtain a silicon-germanium epitaxial intrinsic base region on an upper side of the silicon epitaxial collector region and a silicon-germanium connection base region that connects the polysilicon extrinsic base region and the silicon-germanium epitaxial intrinsic base region.

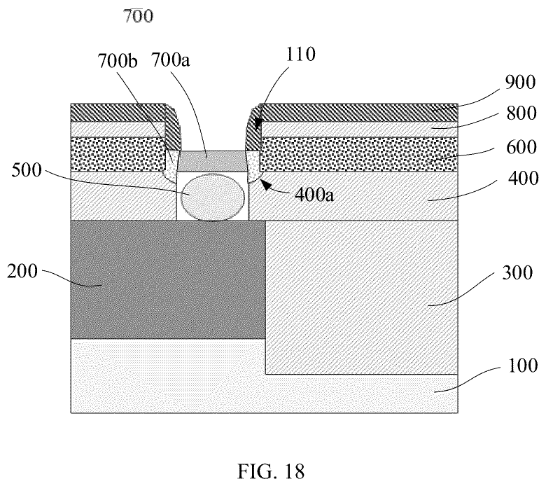

In step S109, as illustrated in FIG. 18, the exposed silicon epitaxial collector region 500 and polysilicon extrinsic base region 600 are taken as seed crystal to grow a silicon-germanium base region 700 with a conductivity type the same as that of the polysilicon extrinsic base region 600, while growing a silicon-germanium epitaxial intrinsic base region 700a above the silicon epitaxial collector region 500 and a recessed silicon-germanium connection base region 700b that connects the polysilicon extrinsic base region 600 and the silicon-germanium epitaxial intrinsic base region 700a; wherein the silicon-germanium base region 700 may be a silicon-germanium layer doped with impurities of the first conductivity type (the same as that of the polysilicon extrinsic base region 600) in situ.

S110: forming an L-shaped silicon oxide inner sidewall inside the silicon nitride inner sidewall.

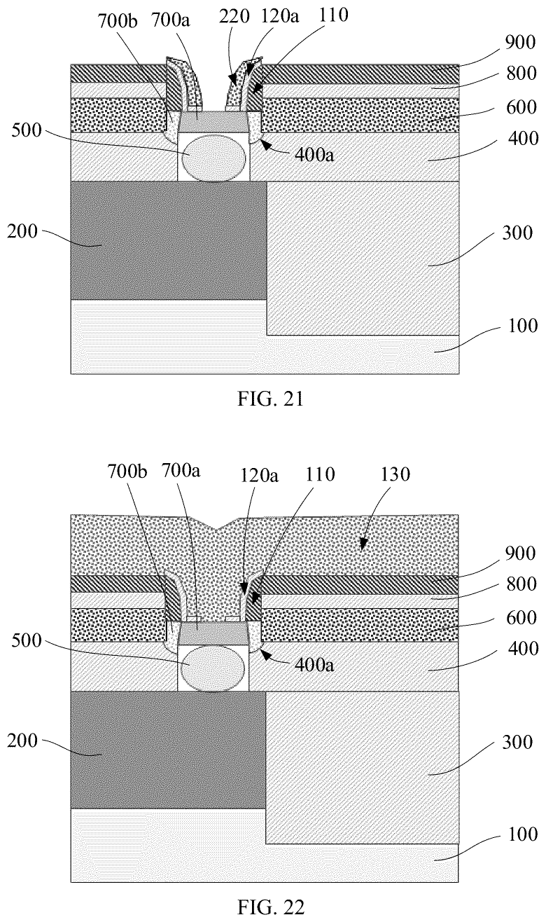

In step S110, as illustrated in FIG. 21, an L-shaped silicon oxide inner sidewall 120a is formed inside the silicon nitride inner sidewall 110.

S111: depositing and forming a polysilicon emitter region with a conductivity type the same as that of the heavily doped silicon collector region;

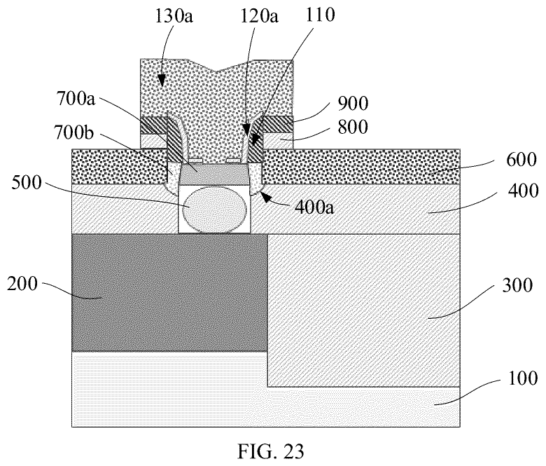

In step S111, as illustrated in FIG. 23, the polysilicon emitter 130a with a conductivity type the same as that of the heavily doped silicon collector region 200 is continuously deposited and formed.

S112: performing rapid thermal annealing, so that impurities in the polysilicon emitter region are diffused into the silicon-germanium epitaxial intrinsic base region to form a single crystal emitter region.

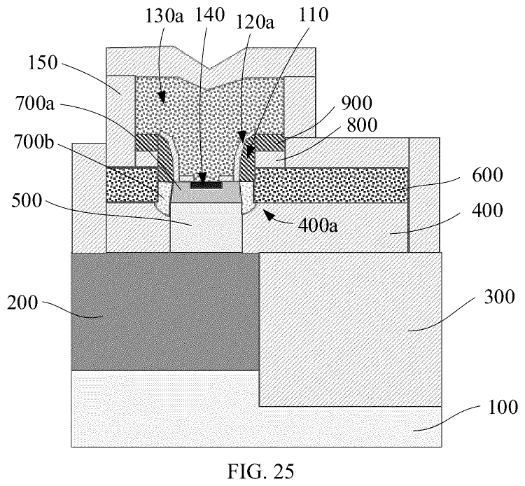

In step S112, as illustrated in FIG. 25, the semiconductor structure formed in the above step is subjected to rapid thermal annealing, so that impurities in the polysilicon emitter 130a are diffused into the silicon-germanium epitaxial intrinsic base region 700a to form a single crystal emitter region 140.

The method for manufacturing the silicon-germanium heterojunction bipolar transistor according to the embodiment of the present disclosure can achieve the purpose of exposing a part of the sidewall of the polysilicon extrinsic base region 600, so as to make a necessary space for subsequently growing the silicon-germanium connection base region 700b synchronously with the silicon-germanium epitaxial intrinsic base region 700a, and implement a recessed silicon-germanium connection base region structure which can effectively improve the device performance. In addition, the silicon-germanium heterojunction bipolar transistor may be manufactured by adopting process steps with low process difficulty and complexity, thus avoiding the uncontrollable process step in the background art of isotropically etching the silicon nitride sidewall by “undercutting” with a bottom slit, and then effectively improving the repeatability, uniformity, controllability and manufacturability of the related integrated circuit process production.

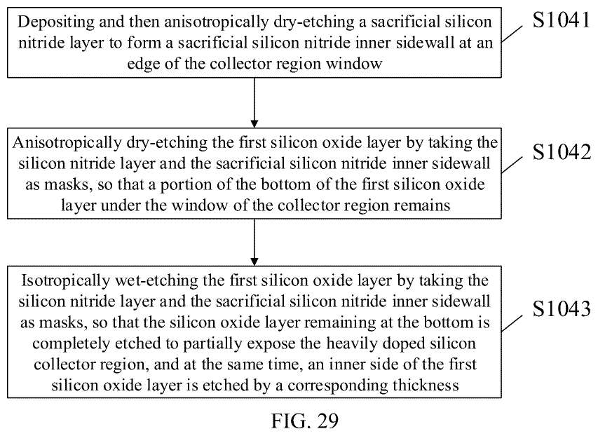

As illustrated in FIG. 29, in some embodiments, etching the first silicon oxide layer below the collector region window to partially expose the heavily doped silicon collector region includes:

S1041: depositing and then anisotropically dry-etching a sacrificial silicon nitride layer to form a sacrificial silicon nitride inner sidewall at an edge of the collector region window.

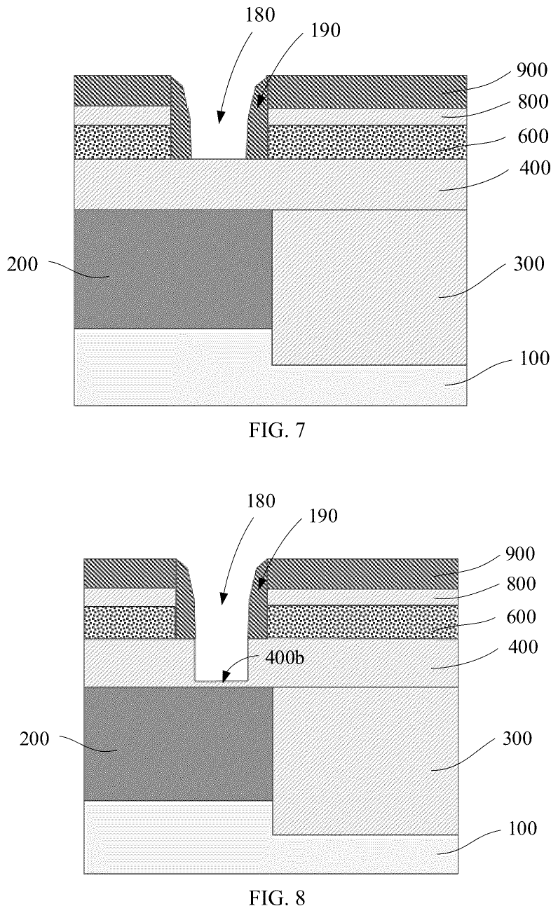

In step S1041, as illustrated in FIG. 7, a sacrificial silicon nitride layer (not illustrated in the FIG.) is deposited and then anisotropically dry-etched to form a sacrificial silicon nitride inner sidewall 190 at an edge of the collector region window 180.

S1042: anisotropically dry-etching the first silicon oxide layer by taking the silicon nitride layer and the sacrificial silicon nitride inner sidewall as masks, so that a portion of the bottom of the first silicon oxide layer under the window of the collector region remains.

In step S1042, as illustrated in FIG. 8, the first silicon oxide layer 400 is anisotropically dry-etched by taking the silicon nitride layer 900 and the sacrificial silicon nitride inner sidewall 190 as masks, so that a thin silicon oxide layer 400b remains at the bottom.

S1043: isotropically wet-etching the first silicon oxide layer by taking the silicon nitride layer and the sacrificial silicon nitride inner sidewall as masks, so that the silicon oxide layer remaining at the bottom is completely etched to partially expose the heavily doped silicon collector region, and at the same time, an inner side of the first silicon oxide layer is etched by a corresponding thickness.

In step S1043, as illustrated in FIG. 9, the first silicon oxide layer 400 is isotropically wet-etched by taking the silicon nitride layer 900 and the sacrificial silicon nitride inner sidewall 190 as masks, so that the silicon oxide layer 400b at the bare bottom is completely etched, and at the same time, an inner side of the first silicon oxide layer 400 is etched by a corresponding thickness.

In some embodiments, after taking the exposed heavily doped silicon collector region as seed crystal to selectively grow a silicon epitaxial collector region, so that an upper surface of the silicon epitaxial collector region is flush with an upper surface of the first silicon oxide layer, and before forming a third silicon oxide layer on the upper surface of the silicon epitaxial collector region, the method further includes: taking the silicon nitride layer, the second silicon oxide layer, the polysilicon extrinsic base region and the sacrificial silicon nitride inner sidewall as masks, performing ion implantation of selectively implanted collector on the silicon epitaxial collector region, wherein the conductivity type of implanted impurities is the same as that of the heavily doped silicon collector region.

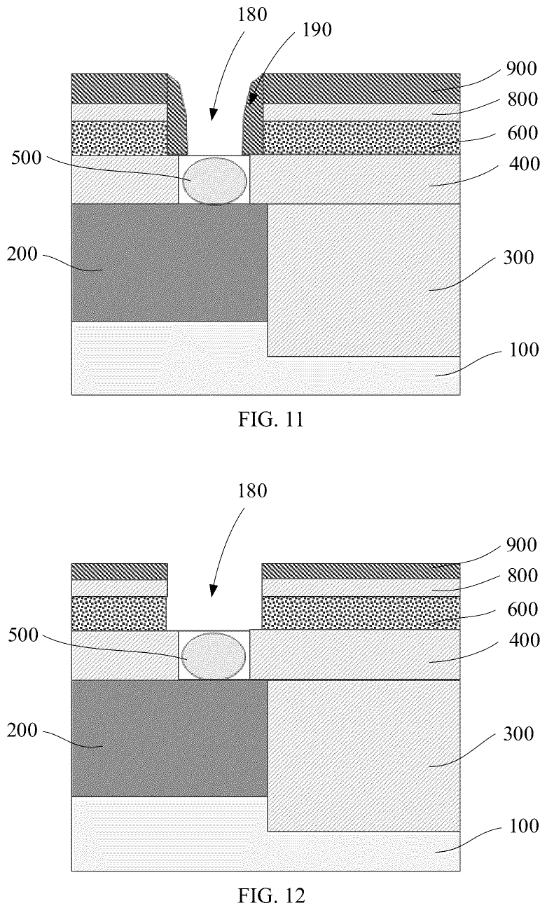

Specifically, as illustrated in FIG. 11, by taking the silicon nitride layer 900, the second silicon oxide layer 800, the polysilicon extrinsic base region 600 and the sacrificial silicon nitride inner sidewall 190 as masks, a selective implantation collector region (SIC) ion implantation is performed on the silicon epitaxial collector region 500, wherein the conductivity type of implanted impurities is the same as that of the heavily doped silicon collector region 200.

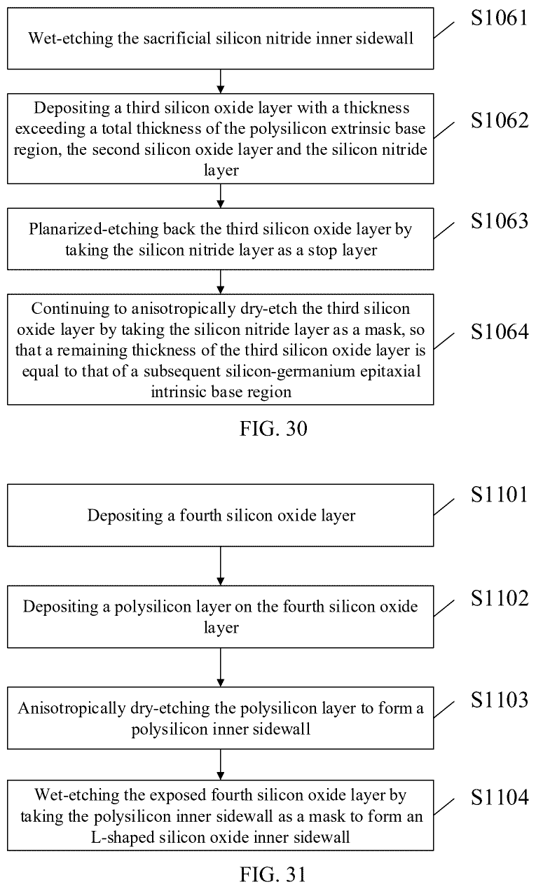

As illustrated in FIG. 30, in some embodiments, forming a third silicon oxide layer on the upper surface of the silicon epitaxial collector region, so that a thickness of the third silicon oxide layer is equal to that of a subsequent silicon-germanium epitaxial intrinsic base region includes:

S1061: wet-etching the sacrificial silicon nitride inner sidewall.

In step S1061, as illustrated in FIG. 12, the sacrificial silicon nitride inner sidewall 190 is wet-etched, and at the same time, a silicon nitride layer with a certain thickness is also lost on an upper surface of the silicon nitride layer 900.

S1062: depositing a third silicon oxide layer with a thickness exceeding a total thickness of the polysilicon extrinsic base region, the second silicon oxide layer and the silicon nitride layer.

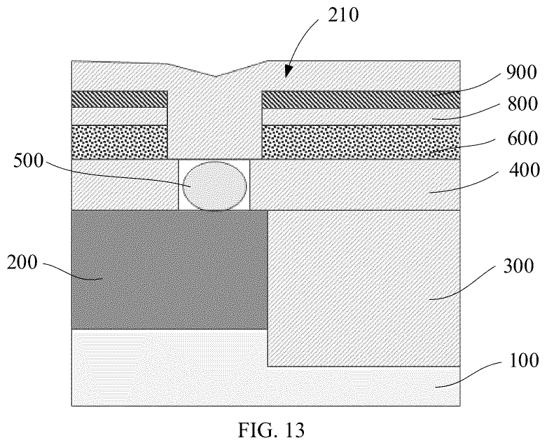

In step S1062, as illustrated in FIG. 13, a third silicon oxide layer 210 with a thickness exceeding a total thickness of the polysilicon extrinsic base region 600, the second silicon oxide layer 800 and the remaining silicon nitride layer 900 is deposited.

S1063: planarized-etching back the third silicon oxide layer by taking the silicon nitride layer as a stop layer.

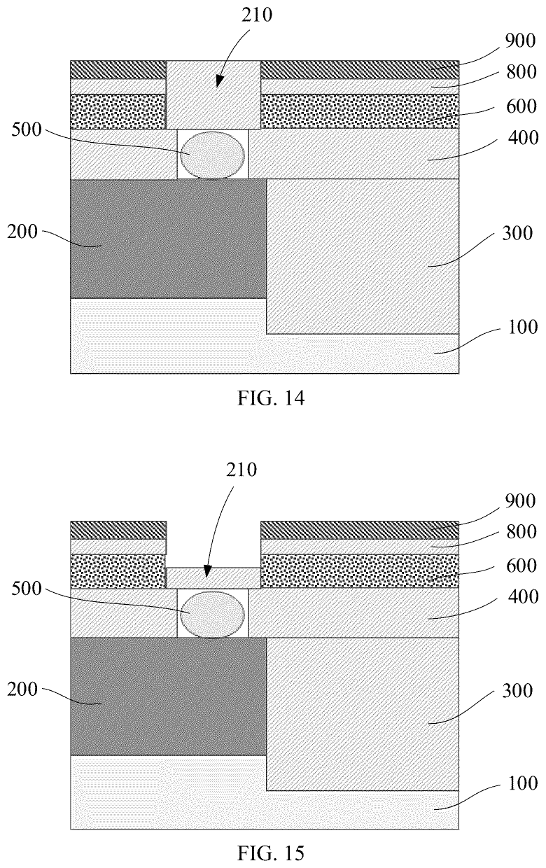

In step S1063, as illustrated in FIG. 14, the third silicon oxide layer 210 on the silicon nitride layer 900 is completely planarized-etched back by taking the silicon nitride layer 900 as a stop layer, and an upper surface of the third silicon oxide layer 210 remaining in the collector region window 180 is flush with an upper surface of the silicon nitride layer 900.

S1064: continuing to anisotropically dry-etch the third silicon oxide layer by taking the silicon nitride layer as a mask, so that a remaining thickness of the third silicon oxide layer is equal to that of a subsequent silicon-germanium epitaxial intrinsic base region.

In step S1064, as illustrated in FIG. 15, the third silicon oxide layer 210 is continued to be anisotropically dry-etched by taking the silicon nitride layer 900 as a mask, so that a remaining thickness of the third silicon oxide layer 210 is equal to that of a subsequent silicon-germanium epitaxial intrinsic base region 700a.

As illustrated in FIG. 31, in some embodiments, forming an L-shaped silicon oxide inner sidewall inside the silicon nitride inner sidewall includes:

S1101: depositing a fourth silicon oxide layer.

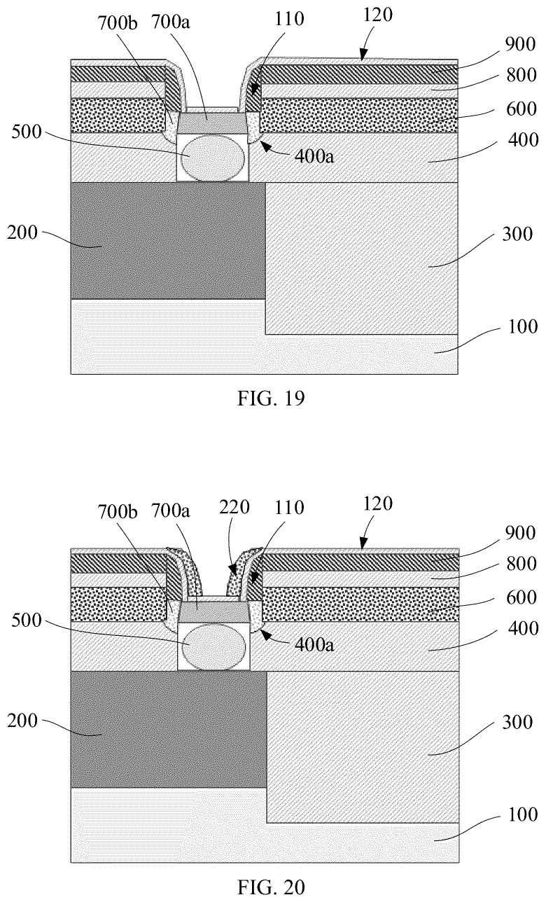

In step S1101, as illustrated in FIG. 19, a fourth silicon oxide layer 120 is deposited.

S1102: depositing a polysilicon layer on the fourth silicon oxide layer.

S1103: anisotropically dry-etching the polysilicon layer to form a polysilicon inner sidewall.

In step S1102 to step S1103, as illustrated in FIG. 20, a polysilicon layer (not illustrated) is deposited on the fourth silicon oxide layer 120, and the polysilicon layer is anisotropically dry-etched to form a polysilicon inner sidewall 220.

S1104: wet-etching the exposed fourth silicon oxide layer by taking the polysilicon inner sidewall as a mask to form an L-shaped silicon oxide inner sidewall.

In step S1104, as illustrated in FIG. 21, the exposed fourth silicon oxide layer 120 is wet-etched by taking the polysilicon inner sidewall 220 as a mask to an L-shaped silicon oxide inner sidewall 120a.

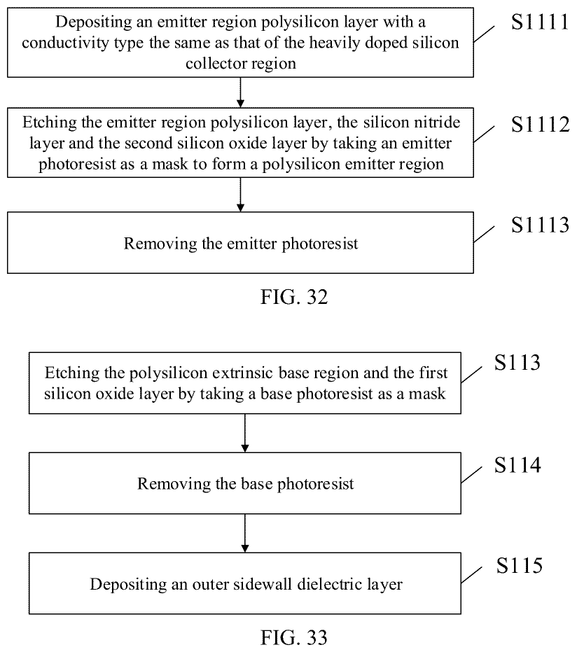

As illustrated in FIG. 32, in some embodiments, depositing and forming a polysilicon emitter region with a conductivity type the same as that of the heavily doped silicon collector region includes:

S1111: depositing an emitter region polysilicon layer with a conductivity type the same as that of the heavily doped silicon collector region.

In step S1111, as illustrated in FIG. 22, an emitter region polysilicon layer 130 is deposited, wherein the emitter region polysilicon layer 130 may be a polysilicon layer heavily doped with impurities of the second conductivity type in situ.

S1112: etching the emitter region polysilicon layer, the silicon nitride layer and the second silicon oxide layer by taking an emitter photoresist as a mask to form a polysilicon emitter region.

In step S1112, as illustrated in FIG. 23, the emitter region polysilicon layer 130, and the silicon nitride layer 900 and the second silicon oxide layer 800 therebelow are sequentially etched by taking an emitter photoresist as a mask to form a polysilicon emitter region 130a.

S1113: removing the emitter photoresist.

As illustrated in FIG. 33, in some embodiments, after removing the emitter photoresist, and before performing rapid thermal annealing, the method further includes:

S113: etching the polysilicon extrinsic base region and the first silicon oxide layer by taking a base photoresist as a mask.

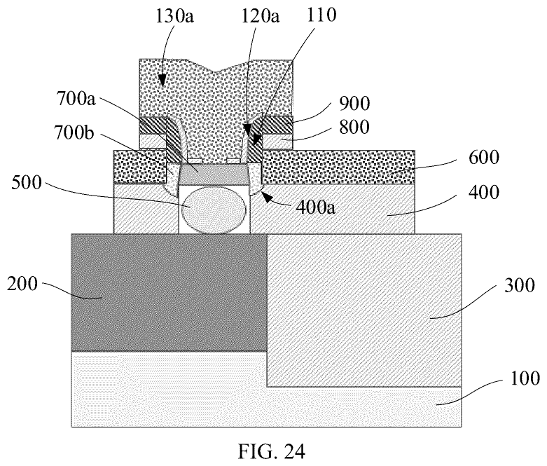

In step S113, as illustrated in FIG. 24, the polysilicon extrinsic base region 600 and the first silicon oxide layer 400 therebelow are sequentially etched by taking the base photoresist as a mask.

S114: removing the base photoresist.

S115: depositing an outer sidewall dielectric layer.

In step S115, as illustrated in FIG. 25, an outer sidewall dielectric layer 150 is deposited.

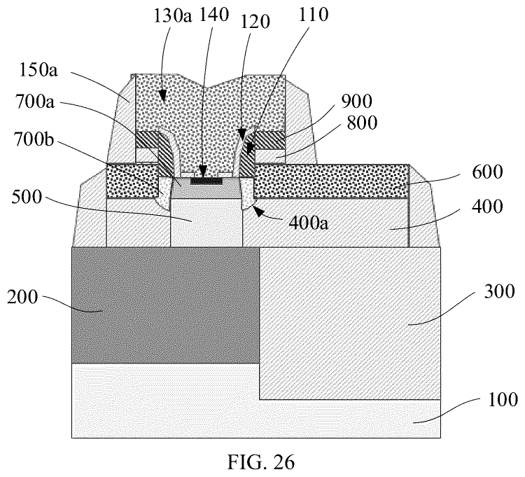

In some embodiments, after performing rapid thermal annealing, so that impurities in the polysilicon emitter region are diffused into the silicon-germanium epitaxial intrinsic base region to form a single crystal emitter region, the method further includes: anisotropically dry-etching the outer sidewall dielectric layer to form a dielectric outer sidewall. Specifically, as illustrated in FIG. 26, the outer sidewall dielectric layer 150 is anisotropically dry-etched to form a dielectric outer sidewall 150a.

In some embodiments, after forming the dielectric outer sidewall, the method further includes: forming a self-aligned silicide layer on the upper sides of the exposed polysilicon emitter region and polysilicon extrinsic base region, wherein the self-aligned silicide layer is self-aligned separated by the dielectric outer sidewall. Specifically, as illustrated in FIG. 27, a low-resistance self-aligned metal silicide layer 160 may be formed by a silicidation reaction between refractory metal and exposed monocrystalline and polycrystalline silicon surfaces, and the self-aligned metal silicide layer 160 is self-aligned separated by the dielectric outer sidewall 150a.

Since the present disclosure has no restriction on the manner of leading out the collector electrode and the substrate electrode of the silicon-germanium heterojunction bipolar transistor in the present disclosure, the led-out electrodes of the collector region and the substrate region are not demonstrated in the process flowcharts of the above specific embodiments.

It should be noted that in the present disclosure, the relational terms such as “first” and “second” are only used to distinguish one entity or operation from another entity or operation, and do not necessarily require or imply any such actual relationship or sequence between these entities or operations. In addition, the term “comprise”, “include” or any other variation thereof is intended to cover non-exclusive inclusions, so that a process, method, article or device that includes a series of elements includes not only those elements, but also other elements not explicitly listed, or further includes elements inherent to such process, method, article or device. Without further restrictions, an element defined by a statement “comprising a . . . ” does not exclude the existence of other identical elements in a process, method, article or device that includes said element. An orientation or positional relationship indicated by a term such as “upper” or “lower” is based on the drawings, only for the convenience of describing the present disclosure and simplifying the description, rather than indicating or implying that the referred device or element must have a specific orientation, or be constructed and operated in a specific orientation, and therefore should not be understood as a limitation to the present disclosure. Unless otherwise specified and limited explicitly, the terms “installation”, “connected” and “connection” should be understood broadly, e.g., it may be possible for a fixed connection, a detachable connection, an integrated connection, a mechanical connection, an electrical connection, a direct connection, an indirect connection through an intermediate medium, or a communication between the interiors of two elements. For those of ordinary skill in the art, the specific meanings of the above terms in the present disclosure can be understood according to specific situations.

The embodiments of the present disclosure are all described in a progressive manner, and the same or similar portions of the embodiments can refer to each other. Each embodiment lays an emphasis on its distinctions from other embodiments. In the description of the present disclosure, the description of reference terms “one embodiment”, “some embodiments”, “an example”, “a specific example” or “some examples” and the like mean that the specific features, structures, materials, or characteristics described in conjunction with the embodiment(s) or example(s) are included in at least one embodiment or example of the present disclosure. In the present disclosure, the schematic expressions of the above terms do not necessarily aim at the same embodiment or example. Moreover, the described specific features, structures, materials, or characteristics may be combined in any one or more embodiments or examples in a suitable manner. In addition, those skilled in the art can combine different embodiments or examples described in the present disclosure and features thereof if there is no contradiction to each other.

Specific embodiments are applied in the present disclosure to set forth the principle and the implementations of the present disclosure, and the description of the above embodiments is only used to help the understanding of the method and the core idea of present disclosure. Meanwhile, according to the idea of present disclosure, those of ordinary skill in the art can make changes in the specific embodiments and the application scope. To sum up, the content of the present disclosure should not be construed as limitations to the present disclosure.

1. A silicon-germanium heterojunction bipolar transistor, comprising:
a substrate;
a heavily doped silicon collector region with a conductivity type opposite to that of the substrate, and formed on an upper side of the substrate;
a field region dielectric layer formed on the upper side of the substrate;
a first silicon oxide layer formed on upper sides of the heavily doped silicon collector region and the field region dielectric layer;
a silicon epitaxial collector region with a conductivity type the same as that of the heavily doped silicon collector region, and formed on the upper side of the heavily doped silicon collector region;
a heavily doped polysilicon extrinsic base region with a conductivity type opposite to that of the heavily doped silicon collector region, and formed on the first silicon oxide layer;
a silicon-germanium base region with a conductivity type the same as that of the polysilicon extrinsic base region, comprising: a silicon-germanium epitaxial intrinsic base region formed on an upper side of the silicon epitaxial collector region, and a silicon-germanium connection base region formed on the upper side of the first silicon oxide layer and between the silicon-germanium epitaxial intrinsic base region and the polysilicon extrinsic base region;
a second silicon oxide layer formed between the polysilicon extrinsic base region and a silicon nitride layer;
the silicon nitride layer formed between the second silicon oxide layer and a polysilicon emitter region;
a silicon nitride inner sidewall formed on an upper side of the silicon-germanium connection base region;
an L-shaped silicon oxide inner sidewall formed on an upper side of the silicon-germanium epitaxial intrinsic base region and inner and upper sides of the silicon nitride inner sidewall;
a heavily doped polysilicon emitter region with a conductivity type the same as that of the heavily doped silicon collector region, and formed on upper sides of the silicon nitride layer, the L-shaped silicon oxide inner sidewall and the silicon-germanium epitaxial intrinsic base region; and
a heavily doped single crystal emitter region with a conductivity type the same as that of the polysilicon emitter region, and formed in the silicon-germanium epitaxial intrinsic base region between the L-shaped silicon oxide inner sidewalls; wherein,
a recessed structure is formed in the first silicon oxide layer close to the silicon epitaxial collector region and the polysilicon extrinsic base region, and the silicon-germanium connection base region is formed on an upper side of the recessed structure of the first silicon oxide layer.

2. The silicon-germanium heterojunction bipolar transistor according to claim 1, further comprising:
a dielectric outer sidewall formed outside the first silicon oxide layer, the polysilicon extrinsic base region, the second silicon oxide layer, the silicon nitride layer and the polysilicon emitter region.

3. The silicon-germanium heterojunction bipolar transistor according to claim 2, further comprising:
a self-aligned silicide layer formed on the upper sides of the polysilicon emitter region and the polysilicon extrinsic base region, and self-aligned separated by the dielectric outer sidewall.

4. A method for manufacturing a silicon-germanium heterojunction bipolar transistor, comprising:
providing a silicon-based bipolar transistor infrastructure, wherein the silicon-based bipolar transistor infrastructure comprises a substrate, and a heavily doped silicon collector region with a conductivity type opposite to that of the substrate and a field region dielectric layer which are formed on the substrate;
sequentially depositing and forming a first silicon oxide layer, a heavily doped polysilicon extrinsic base region with a conductivity type opposite to that of the heavily doped silicon collector region, a second silicon oxide layer and a silicon nitride layer on the silicon-based bipolar transistor infrastructure;
forming a collector region window along a thickness direction of the silicon nitride layer, the second silicon oxide layer and the polysilicon extrinsic base region to partially expose the first silicon oxide layer;
etching the first silicon oxide layer below the collector region window to partially expose the heavily doped silicon collector region;
taking the exposed heavily doped silicon collector region as seed crystal to selectively grow a silicon epitaxial collector region, so that an upper surface of the silicon epitaxial collector region is flush with an upper surface of the first silicon oxide layer;
forming a third silicon oxide layer on the upper surface of the silicon epitaxial collector region, so that a thickness of the third silicon oxide layer is equal to that of a subsequent silicon-germanium epitaxial intrinsic base region;
forming a silicon nitride inner sidewall on an edge of the collector region window on an upper side of the third silicon oxide layer;
wet-etching the third silicon oxide layer, and etching a part of the first silicon oxide layer under the third silicon oxide layer, so as to form a recessed structure at the junction of the first silicon oxide layer with the silicon epitaxial collector region and the polysilicon extrinsic base region;
taking the exposed silicon epitaxial collector region and polysilicon extrinsic base region as seed crystal to grow a silicon-germanium base region with a conductivity type the same as that of the polysilicon extrinsic base region, to obtain a silicon-germanium epitaxial intrinsic base region on an upper side of the silicon epitaxial collector region and a silicon-germanium connection base region that connects the polysilicon extrinsic base region and the silicon-germanium epitaxial intrinsic base region;
forming an L-shaped silicon oxide inner sidewall inside the silicon nitride inner sidewall;
depositing and forming a polysilicon emitter region with a conductivity type the same as that of the heavily doped silicon collector region; and
performing rapid thermal annealing, so that impurities in the polysilicon emitter region are diffused into the silicon-germanium epitaxial intrinsic base region to form a single crystal emitter region.

5. The method according to claim 4, wherein etching the first silicon oxide layer below the collector region window to partially expose the heavily doped silicon collector region comprises:
depositing and then anisotropically dry-etching a sacrificial silicon nitride layer to form a sacrificial silicon nitride inner sidewall at an edge of the collector region window;
anisotropically dry-etching the first silicon oxide layer by taking the silicon nitride layer and the sacrificial silicon nitride inner sidewall as masks, so that a portion of the bottom of the first silicon oxide layer under the window of the collector region remains; and
isotropically wet-etching the first silicon oxide layer by taking the silicon nitride layer and the sacrificial silicon nitride inner sidewall as masks, so that the silicon oxide layer remaining at the bottom is completely etched to partially expose the heavily doped silicon collector region, and at the same time, an inner side of the first silicon oxide layer is etched by a corresponding thickness.

6. The method according to claim 5, wherein after taking the exposed heavily doped silicon collector region as seed crystal to selectively grow a silicon epitaxial collector region, so that an upper surface of the silicon epitaxial collector region is flush with an upper surface of the first silicon oxide layer, and before forming a third silicon oxide layer on the upper surface of the silicon epitaxial collector region, the method further comprises:
taking the silicon nitride layer, the second silicon oxide layer, the polysilicon extrinsic base region and the sacrificial silicon nitride inner sidewall as masks, performing ion implantation of selectively implanted collector on the silicon epitaxial collector region, wherein the conductivity type of implanted impurities is the same as that of the heavily doped silicon collector region.

7. The method according to claim 5, wherein forming a third silicon oxide layer on the upper surface of the silicon epitaxial collector region, so that a thickness of the third silicon oxide layer is equal to that of a subsequent silicon-germanium epitaxial intrinsic base region comprises:
wet-etching the sacrificial silicon nitride inner sidewall;
depositing a third silicon oxide layer with a thickness exceeding a total thickness of the polysilicon extrinsic base region, the second silicon oxide layer and the silicon nitride layer;
planarized-etching back the third silicon oxide layer by taking the silicon nitride layer as a stop layer; and
continuing to anisotropically dry-etch the third silicon oxide layer by taking the silicon nitride layer as a mask, so that a remaining thickness of the third silicon oxide layer is equal to that of a subsequent silicon-germanium epitaxial intrinsic base region.

8. The method according to claim 7, wherein forming an L-shaped silicon oxide inner sidewall inside the silicon nitride inner sidewall comprises:
depositing a fourth silicon oxide layer;
depositing a polysilicon layer on the fourth silicon oxide layer;
anisotropically dry-etching the polysilicon layer to form a polysilicon inner sidewall; and
wet-etching the exposed fourth silicon oxide layer by taking the polysilicon inner sidewall as a mask to form an L-shaped silicon oxide inner sidewall.

9. The method according to claim 8, wherein depositing and forming a polysilicon emitter region with a conductivity type the same as that of the heavily doped silicon collector region comprises:
depositing an emitter region polysilicon layer with a conductivity type the same as that of the heavily doped silicon collector region;
etching the emitter region polysilicon layer, the silicon nitride layer and the second silicon oxide layer by taking an emitter photoresist as a mask to form a polysilicon emitter region; and
removing the emitter photoresist.

10. The method according to claim 9, wherein after removing the emitter photoresist, and before performing rapid thermal annealing, the method further comprises:
etching the polysilicon extrinsic base region and the first silicon oxide layer by taking a base photoresist as a mask;
removing the base photoresist; and
depositing an outer sidewall dielectric layer;
after performing rapid thermal annealing, so that impurities in the polysilicon emitter region are diffused into the silicon-germanium epitaxial intrinsic base region to form a single crystal emitter region, the method further comprises:
anisotropically dry-etching the outer sidewall dielectric layer to form a dielectric outer sidewall.

11. The method according to claim 10, wherein after forming the dielectric outer sidewall, the method further comprises:
forming a self-aligned silicide layer on the upper sides of the exposed polysilicon emitter region and polysilicon extrinsic base region, wherein the self-aligned silicide layer is self-aligned separated by the dielectric outer sidewall.
